(19) United States
(12) Patent Application Publication
(10) Pub. No.: US 2014/0001486 A1
(43) Pub. Date: Jan. 2, 2014

(54) COMPOSITE SEMIDCONDUCTOR SUBSTRATE, SEMICONDUCTOR DEVICE, AND MANUFACTURING METHOD

(71) Applicants: Vladislav E. Bougrov, Saint-Petersburg (RU); Maxim A. Odnoblyudov, Saint-Petersburg (RU); Alexey Romanov, Saint-Petersburg (RU); Vladimir Nikolaev, Saint-Petersburg (RU)

(72) Inventors: Vladislav E. Bougrov, Saint-Petersburg (RU); Maxim A. Odnoblyudov, Saint-Petersburg (RU); Alexey Romanov, Saint-Petersburg (RU); Vladimir Nikolaev, Saint-Petersburg (RU)

(73) Assignees: PERFECT CRYSTALS LLC, Saint-Petersburg (RU); OPTOGAN OY, Espoo (FI)

(21) Appl. No.: 14/005,023

(22) PCT Filed: Mar. 14, 2012
(86) PCT No.: PCT/FI2012/050241

§ 371 Date: Sep. 13, 2013

(30) Foreign Application Priority Data
Mar. 14, 2011 (FI) 20115255

(51) Int. Cl. H01L 29/20; H01L 21/02

(52) U.S. Cl. CPC H01L 29/2003; H01L 21/0254
USPC 257/76; 438/458

(57) ABSTRACT

According to the present invention, a composite semiconductor substrate (1) for epitaxial growth of a compound semiconductor material (1) comprises a ceramic semiconductor support layer (4), and a single crystalline epitaxial layer (3) formed of the compound semi-conductor material on the ceramic semiconductor support layer.

### FIELD OF THE INVENTION

The present invention relates to substrates, and manufacturing thereof, for epitaxial growth of semiconductor structures and devices, particularly to structures and devices formed of compound semiconductors.

### BACKGROUND OF THE INVENTION

In epitaxial growth of semiconductor structures and devices, a substrate is needed on which the growth of the semiconductor material is initiated, and which serves as a support for the grown semiconductor layers.

The properties of the substrate play a key role in the quality of the epitaxially grown semiconductor layers. For example, a lattice mismatch between the substrate and the semiconductor material epitaxially grown on it causes stresses and can result in formation of dislocations in the latter, and can thus deteriorate significantly the performance of a semiconductor device, e.g. a light emitting diode LED, formed on the substrate. Also a difference in the thermal expansion coefficient between the substrate and the epitaxially grown layers can induce stresses in the latter. Thus, most preferably, the substrate should be formed of the material to be grown epitaxially thereon. This kind of situation where the substrate and the epitaxially grown layers are of the same material is called homoepitaxy.

Unfortunately, some widely used compound semiconductor materials such as, for example, gallium nitride GaN and other III-nitrides, have significant problems in their bulk fabrication. Production of bulk material in the form of single-crystal wafers can be so challenging and expensive that it is not suitable for industrial-scale manufacturing. In such cases, heterosubstrates (also known as foreign substrates), i.e. substrates formed of a material different from the material to be epitaxially grown, must be used. However, despite of carefully optimizing the substrate material for the actual semiconductor material at issue, the effects of crystal lattice mismatch and difference in thermal expansion between the heterosubstrate and the material to be grown on it are difficult if not impossible to eliminate entirely. To avoid these undesirable effects, different kinds of semiconductor templates have been developed for epitaxial growth of different materials. Templates are typically multi-layered epitaxial structures adjusted to the heterosubstrate with a cap layer made of a material optimized for later epitaxial growth of the semiconductor device structures. By using such templates, e.g. GaN devices can be grown on sapphire. Such a template improves the quality of the epitaxial layers but is still not able to sufficiently suppress generation of thermo-mechanical stresses.

Hence, there is a strong need for effective and low cost solutions for providing substrates for epitaxial growth of high-quality compound semiconductor layers thereon.

### OBJECT OF THE INVENTION

It is an object of the present invention to provide novel, low-cost substrates for epitaxial growth of high-quality compound semiconductor structures and devices. It is also an object of the present invention to provide semiconductor devices formed on, as well as a method for manufacturing such substrates.

### SUMMARY OF THE INVENTION

The present invention utilizes the possibilities provided by semiconductor bulk ceramics, i.e. non-metallic semiconductor materials, fabricated from particles (crystals) of semiconductor materials, having a polycrystalline or amorphous structure. In general, semiconductor ceramics meant here can be e.g. composite material comprising a mixture of polycrystalline texture and solid particles, the both phases having the same composition. Important properties of ceramic semiconductor materials include, for example, more isotropic physical and mechanical properties in comparison to single-crystal or polycrystalline material structure. In the present invention, an important feature of the ceramic semiconductor materials is also their low manufacturing costs in comparison to the complex multi-layered templates.

According to a first aspect, the present invention provides a novel composite semiconductor substrate for epitaxial growth of a compound semiconductor material, i.e. a substrate on which the compound semiconductor material can be epitaxially grown.

The composite semiconductor substrate comprises a ceramic semiconductor support layer, and a single crystalline epitaxial layer, formed of the compound semiconductor material, on the ceramic semiconductor support layer. In principle, the purpose of the ceramic semiconductor support layer is to serve as a mechanical support for the possibly very thin epitaxial layer. In this purpose, a ceramic support layer provides a cost-efficient alternative for the conventional foreign substrates or multi-layered templates. Moreover, it is more suitable for process operations than e.g. a foreign substrate. The epitaxial layer, in turn, serves as a homoepitaxy growth surface for later epitaxial growth of the compound semiconductor material. Homoepitaxial growth of the compound semiconductor material on the epitaxial layer, which has high quality and is formed of the same compound semiconductor material, enables production of high-quality semiconductor device layers with effectively diminished stresses and dislocations.

To minimize the stresses induced by lattice misfit and/or thermal expansion differences in the composite semiconductor substrate and the epitaxial compound semiconductor material later grown on it, the material of the ceramic semiconductor support layer should have an average lattice constant and a thermal expansion coefficient similar to those of the compound semiconductor material. Preferably, the ceramic semiconductor support layer is formed of the compound semiconductor material, i.e. the same material having the same composition as the single crystalline epitaxial layer. Such composite substrate has low internal residual stresses and provides especially low misfit to the compound semiconductor layers epitaxially grown on the substrate.

In one preferred embodiment, the compound semiconductor material comprises a group III nitride, e.g. gallium nitride GaN. Another useful material is aluminium nitride AlN. These nitrides are important materials e.g. in the field of light emitting diodes LEDs.

Preferably, the epitaxial layer has a thickness of 1 to 100 μm. To provide sufficiently rigid and robust support for such a thin epitaxial layer, the ceramic semiconductor support layer has preferably a thickness of at least 0.1 mm.

According to a second aspect, the present invention provides a semiconductor device comprising a composite semiconductor substrate as defined above, and one or more device layers formed of the compound semiconductor material by epitaxial growth on the single crystalline epitaxial layer of the composite substrate. The device can be, for example, a light emitting semiconductor device such as a light emitting diode LED or a laser diode.

According to a third aspect, the present invention provides a novel method for manufacturing a composite semiconductor substrate as defined above. The method comprises the steps of (i) depositing a single crystalline epitaxial layer of the compound semiconductor material on a foreign substrate; (ii) forming a ceramic semiconductor support layer attached on the epitaxial layer; and (iii) removing the foreign substrate.

In depositing the single crystalline epitaxial layer of the compound semiconductor material, any known processes, e.g. chemical vapor deposition CVD and sputtering, and equipment suitable for epitaxial growth of semiconductors can be used.

By foreign substrate is meant here a substrate formed of a material different from the material of the epitaxial layer. Thus, the basic principle of the method is to first form a high-quality epitaxial layer on a temporary foreign substrate, then attach a ceramic semiconductor support layer on the epitaxial layer, and finally remove, e.g. by lift-off, the temporary foreign substrate.

In one embodiment, the step of forming the ceramic semiconductor support layer attached on the epitaxial layer comprises growing the ceramic semiconductor support layer on the epitaxial layer. In other words, the ceramic support layer can be formed directly on the epitaxial layer.

In an alternative embodiment, the step of forming the ceramic semiconductor layer attached on the epitaxial layer comprises forming a ceramic semiconductor support layer, and attaching the thus formed support layer on the epitaxial layer. Thus, in this embodiment the ceramic semiconductor support layer can be formed separately and attached then to the epitaxial layer, e.g. by wet or dry bonding. In the case of bonding, an interface bonding layer can be used in order to improve the bonding process. Whatever technique is used to attach the ceramic semiconductor support layer to the epitaxial layer, the technique should provide an attachment which is compatible with later high-temperature deposition, e.g. by CVD, of the compound semiconductor material on the composite semiconductor substrate.

The most conventional method of forming ceramic materials is sintering of a powder. In the method according to the present invention, other useful techniques are, for example, chemical vapor deposition CVD, metal-organic vapor phase deposition MOVPE, different plasma-assisted deposition methods, and sol-gel processes. Sol-gel technology can be also used in attaching a pre-fabricated ceramic semiconductor support layer to the epitaxial layer.

To summarize, the overall key principle of the composite semiconductor substrate according to the present invention is the utilization of the single crystal epitaxial layer and the ceramic support layer made of the same or at least a similar material with sufficiently similar average lattice parameter and thermal expansion coefficient. After removing the foreign substrate, such composite semiconductor substrate serves as an ideal substrate for later epitaxial growth of compound semiconductor device structures thereon.

### DETAILED DESCRIPTION OF THE INVENTION

The present invention is described in more detail in the following with reference to the accompanying figures.

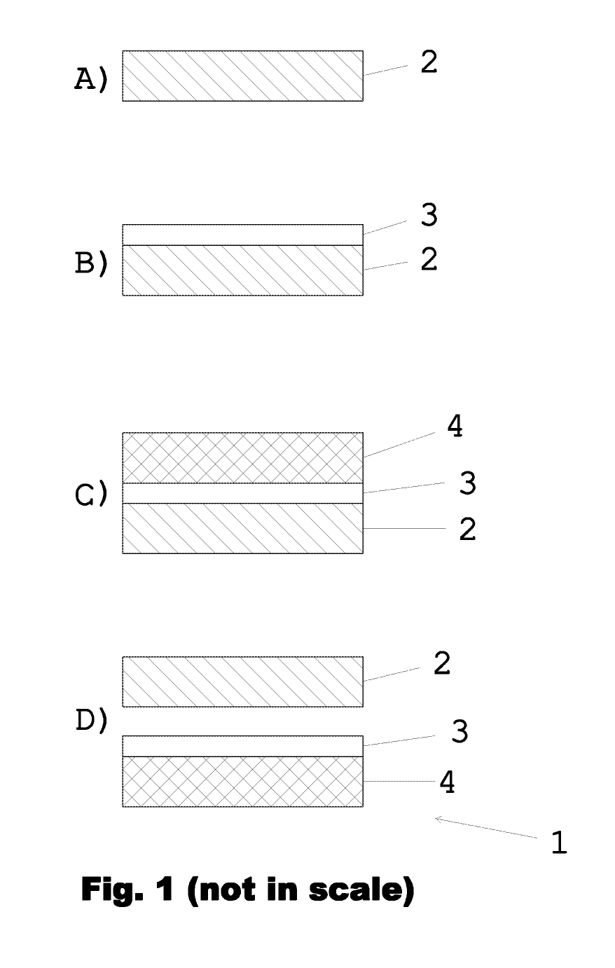

FIG. 1 illustrates a composite semiconductor substrate 1 for epitaxial growth of a compound semiconductor material, and manufacturing thereof, according to the present invention. In the method, first a foreign substrate 2, i.e. a substrate of a material different from the compound semiconductor and suitable for epitaxial growth of the compound semiconductor, is provided (step A). Material of the substrate can be e.g. sapphire. Next (step B), thin compound semiconductor epitaxial layer 3 of group III nitride with a thickness of 1 to 100 μm, e.g. about 50 μm, is deposited on the foreign substrate 2. This is followed by growth (step C) of a ceramic support layer 4 (made of the same or related compound semiconductor) directly, or by first depositing or otherwise providing some intermediate layer, on the epitaxial layer. The ceramic support layer 4 has a thickness of at least 0.1 mm, e.g. 0.2 to 0.3 mm in order to provide sufficient mechanical strength. Finally, the foreign substrate 2 is separated from the epitaxial layer 3 by lift-off (step D), thereby producing a complete composite semiconductor substrate 1.

The composite semiconductor substrate 1 thus formed, comprising a relatively thick (bulk) ceramic support layer 4 and a thin single crystalline compound semiconductor epitaxial layer 3 can be used, for example, for forming compound semiconductor device layers and other structures by homoepitaxial growth on the composite substrate.

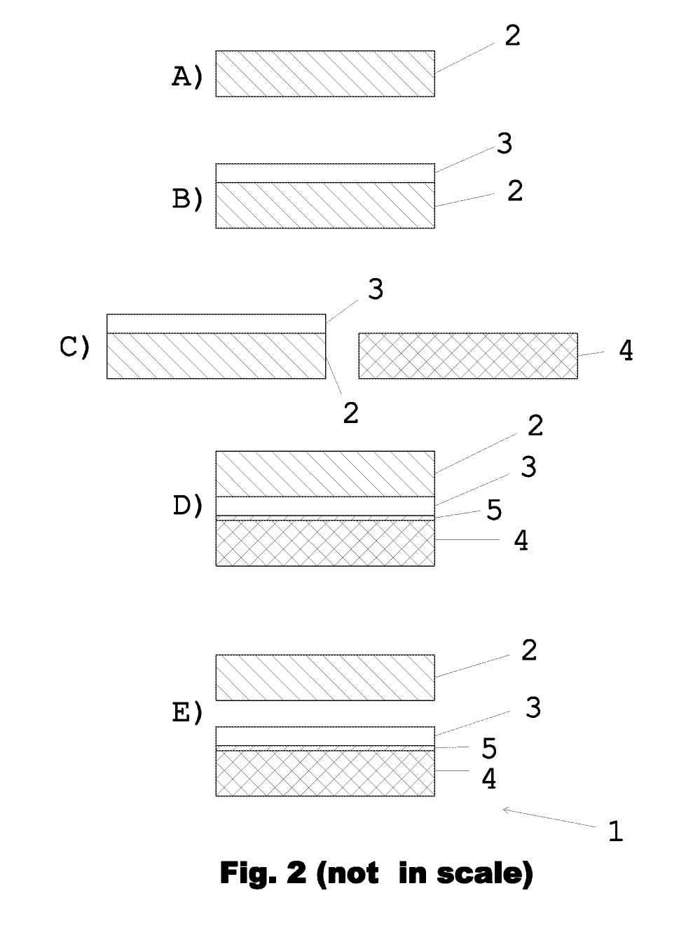

Another alternative for manufacturing a composite semiconductor substrate according to the present invention is presented in FIG. 2.

In the approach of FIG. 2, the ceramic semiconductor support layer 4 is fabricated separately (step C), e.g. by sintering, and attached, e.g. by dry or wet bonding, to the epitaxial layer/foreign substrate stack 2, 3. A sufficiently strong adhesion between the ceramic support layer and the epitaxial layer can be achieved via an interface bonding layer 5. As a simple alternative to bonding, the ceramic support layer 4 can be glued to the epitaxial layer 3 by means of a glue having a composition compatible with the epitaxial layer and the ceramic support layer material(s). For example, the glue can be an aqueous solution of ceramic particles with a composition similar to that of the epitaxial and ceramic support layers. Finally, as in the process of FIG. 1, the foreign substrate 2 is separated from the epitaxial layer 3, thereby resulting in a complete free-standing composite semiconductor substrate 1.

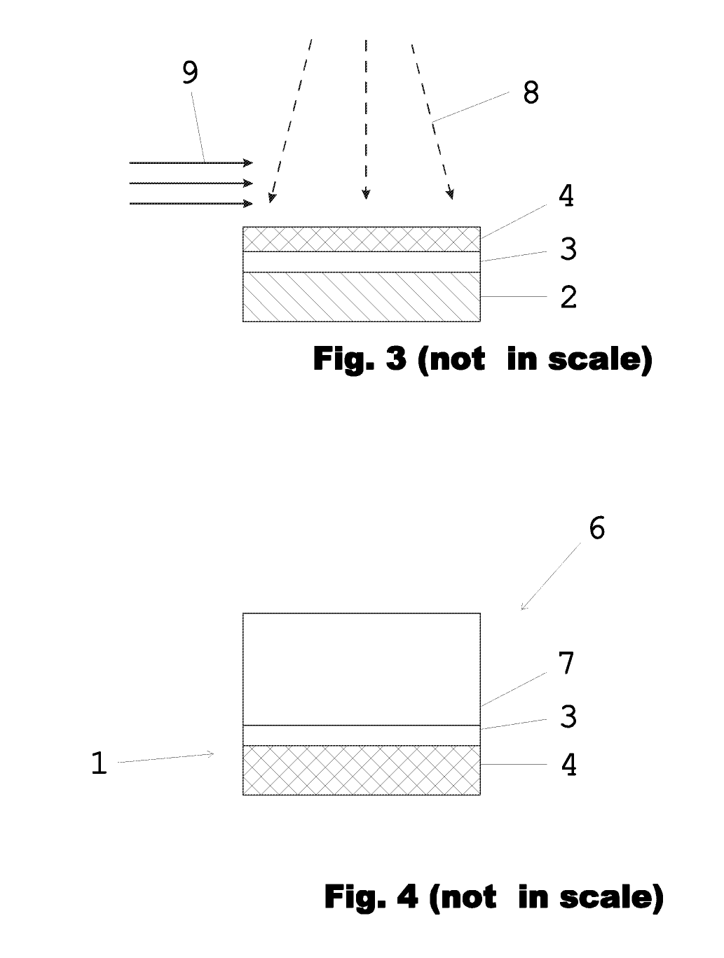

FIG. 3 illustrates the principle of a preferred embodiment of growing the ceramic semiconductor support layer 4 directly on the epitaxial layer. In the illustrated scheme, a CVD process is combined with sputtering of solid semiconductor particles 8 of the compound semiconductor material, e.g. GaN. Both the CVD flow 9 and the particles 8 are applied to the vicinity of the surface of the epitaxial layer 3 serving as the growth substrate. As result, ceramic GaN support layer 4 is formed on the epitaxial layer. The formation of the ceramic GaN is controlled by adjusting the CVD gas flow: strong flow leads to ceramics, whereas a low flow results in formation of polycrystalline GaN structure.

FIG. 4 shows as a simplified schematic a light emitting device 6, e.g. a LED, comprising a composite semiconductor substrate 1 according to the present invention. The device comprises one or more device layers 7, e.g. of GaN, formed by epitaxial growth on the composite semiconductor substrate 1 comprising a ceramic semiconductor support layer 4 and a single crystalline epitaxial layer 3.

1. A composite semiconductor substrate (1) for epitaxial growth of a compound semiconductor material, wherein the composite substrate comprises a ceramic semiconductor support layer, and a single crystalline epitaxial layer, formed of the compound semiconductor material, on the ceramic semiconductor support layer.

2. A composite semiconductor substrate as defined in claim 1, wherein the ceramic semiconductor support layer is formed of the compound semiconductor material.

3. A composite semiconductor substrate as defined in claim 1, wherein the compound semiconductor material comprises a group III nitride.

4. A composite semiconductor substrate as defined in claim 3, wherein the compound semiconductor material comprises gallium nitride GaN.

5. A composite semiconductor substrate as defined in any of claim 1, wherein the single crystalline epitaxial layer has a thickness of 1 to 100 μm.

6. A composite semiconductor substrate as defined in claim 5, wherein and the ceramic semiconductor support layer has a thickness of at least 0.1 mm.

7. A semiconductor device comprising a composite semiconductor substrate as defined in any of claim 1, and one or more device layers formed of the compound semiconductor material by epitaxial growth on the single crystalline epitaxial layer of the composite substrate.

8. A method for manufacturing a composite semiconductor substrate according to any of claim 1, the method comprising the steps of:
depositing a single crystalline epitaxial layer of the compound semiconductor material on a foreign substrate;
forming a ceramic semiconductor support layer attached on the epitaxial layer; and
removing the foreign substrate.

9. A method as defined in claim 8, wherein the step of forming the ceramic semiconductor support layer attached on the epitaxial layer comprises growing the ceramic semiconductor support layer on the epitaxial layer.

10. A method as defined in claim 8, wherein the step of forming the ceramic semiconductor support layer attached on the epitaxial layer comprises forming a ceramic semiconductor support layer, and attaching the thus formed support layer on the epitaxial layer.
